(19) United States
(12) Patent Application Publication
(10) Pub. No.: US 2010/0205386 A1
(43) Pub. Date: Aug. 12, 2010

(54) Memory controller and memory control method

(75) Inventor: Haruki Yamashita, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/656,482

(22) Filed: Feb. 1, 2010

(30) Foreign Application Priority Data
Feb. 6, 2009 (JP) 25896/2009

(51) Int. Cl. G06F 12/00; G11C 7/00

(52) U.S. Cl. 711/154; 365/194; 365/193; 711/E12.001

(57) ABSTRACT

In order to provide a memory controller capable of calibrating a memory access timing even in a case where an application has no blanking interval, the memory controller includes: a delay circuit (3) for delaying data strobe signals; at least two FIFO buffer units (7, 8, and 9) for storing data values of data signals transmitted from a memory based on at least two of the data strobe signals delayed by the delay circuit (3), respectively; a comparator (4) for comparing the data values stored in the at least two FIFO buffer units; and a control circuit (6) for controlling delay time periods for the at least two of the data strobe signals by using the delay circuit (3) based on comparison results (10) acquired from the comparator (4). Further, one of the data values stored in the at least two FIFO buffer units is used also for normal operation.

### BACKGROUND OF THE INVENTION

1. Field of the Invention

The present invention relates to a memory controller and a memory control method, and more particularly, to a memory controller and a memory control method for a double data rate synchronous dynamic random access memory (DDR-SDRAM).

2. Description of the Related Art

A DDR-SDRAM is a type of synchronous DRAM to and from which signals are input and output in synchronization with a clock signal. Data is input and output in synchronization with both a rising edge (leading edge) and a falling edge (trailing edge) of the clock signal, to thereby realize a transfer rate twice as high as a transfer rate determined based on a value of a clock frequency.

Timing calibration performed on a controller side when data is read from the DDR-SDRAM has an important role along with improvement in memory speed, and currently a calibration function such as an automatic calibration function has been becoming the mainstream.

In a typical method used in a controller for a DDR2-SDRAM, expected value data is first written into the DRAM, and then a data signal (DQ signal) and a data strobe signal (DQS signal) are fetched from the DRAM to the controller, to thereby calibrate a timing of the data strobe signal (DQS signal).

In this method, immediately after the system is powered on and initialization of the DRAM is completed, the timing calibration is performed on the controller side, and thereafter, normal operation (memory access) is performed. When the timing is actually calibrated, operation is performed such that specific data (expected value) is read from and written into a specific address, while inside the controller, control on a delay element installed thereto and results of collating the expected values of the read data are associated to each other, to thereby set an optimal point at which the data strobe signal captures the data signal.

FIG. 4 illustrates a memory access circuit 102 disclosed in JP 2005-141725 A. The memory access circuit 102 illustrated in FIG. 4 includes a memory 112, a clock generation circuit 110 for generating a reference clock signal 113, and a clock delay calibration circuit 111 for generating a delayed clock signal 114 obtained by delaying the reference clock signal 113. In this case, the clock delay calibration circuit 111 generates a plurality of the delayed clock signals 114 having different delay values.

The memory access circuit 102 further includes a test data generation circuit 105 for generating test data, and a memory access test control circuit 103 for outputting a memory test start signal in response to an external synchronization signal 115. The test data generation circuit 105 generates test data in response to the memory test start signal. Then, the test data generation circuit 105 writes the test data into the memory 112 in synchronization with the reference clock signal 113, and at the same time, outputs write data corresponding to the test data in synchronization with the reference clock signal 113. The memory access test control circuit 103 reads the test data from the memory 112 in synchronization with the delayed clock signal 114, and compares the read test data with the write data, to thereby execute the calibration of the memory access timing to be performed on the memory access circuit 102 according to the comparison result.

In the memory access circuit 102, the external synchronization signal 115 is a signal as illustrated in FIG. 5. The external synchronization signal 115 contains a first signal and a second signal, and has a blanking interval 116 between the first signal and the second signal. At the blanking interval 116, no data signal is contained in the external synchronization signal 115. The memory access test control circuit 103 executes the calibration of the memory access timing on the memory access circuit 102 within the blanking interval 116. As described above, calibration of the memory access timing by using the external synchronization signal 115 having the blanking interval 116 enables effective use of the intervals at which normal memory access is not performed.

However, the memory access circuit 102 disclosed in JP 2005-141725 A has a premise that an application has blanking intervals. Therefore, in order to calibrate the memory access timing, an element which decreases the band, that is, the blanking interval is essential. Meanwhile, in an application having no blanking interval (such as server), the memory access timing may not be calibrated after the memory access timing has been calibrated in an initial state in which the system has been powered on. As a result, the memory access timing may not be calibrated according to the change of environmental conditions due to fluctuations in temperature and voltages.

### SUMMARY OF THE INVENTION

A memory controller according to the present invention includes: a delay circuit for delaying data strobe signals; at least two first-in first-out (FIFO) buffer units for storing data values of data signals transmitted from a memory based on at least two of the data strobe signals delayed by the delay circuit, respectively; a comparator for comparing the data values stored in the at least two FIFO buffer units; and a control circuit for controlling delay time periods for the at least two of the data strobe signals based on comparison results acquired from the comparator. Further, one of the data values stored in the at least two FIFO buffer units is used also for normal operation.

With the memory controller according to the present invention, it is possible to calibrate a memory access timing even in a case where an application has no blanking interval because, in parallel to actual memory access operation, the data values may be compared based on the at least two of the delayed data strobe signals, and the delay time periods may be controlled based on the comparison results.

Further, a memory control method according to the present invention includes: generating at least two delayed data strobe signals; storing data values of data signals transmitted from a memory based on the at least two delayed data strobe signals; comparing the stored data values; controlling delay time periods for the at least two delayed data strobe signals based on comparison results obtained through the comparing; and using one of the data values also for normal operation.

With the memory control method according to the present invention, it is possible to calibrate a memory access timing even in a case where an application has no blanking interval because, in parallel to actual memory access operation, the data values may be compared based on the at least two delayed data strobe signals, and the delay time periods may be controlled based on the comparison results.

According to the present invention, it is possible to provide the memory controller and the memory control method which are capable of calibrating the memory access timing even in the case where the application has no blanking interval.

### BRIEF DESCRIPTION OF THE DRAWINGS

In the accompanying drawings:

FIG. 1 is a diagram illustrating a memory controller according to an embodiment of the present invention;

FIG. 2A is an explanatory diagram illustrating a DQ effective field of the memory controller according to the embodiment of the present invention;

FIG. 2B is an explanatory diagram illustrating correction of a phase position of a DQS signal;

FIG. 2C is another explanatory diagram illustrating the correction of the phase position of the DQS signal;

FIG. 3 is a flow chart illustrating operation of the memory controller according to the embodiment of the present invention;

FIG. 4 is a diagram illustrating a memory access circuit according to a conventional technology; and

FIG. 5 is a diagram illustrating a synchronization signal input to the memory access circuit and a timing of a memory access test performed on the memory access circuit according to the conventional technology.

### DETAILED DESCRIPTION OF THE PREFERRED EMBODIMENT

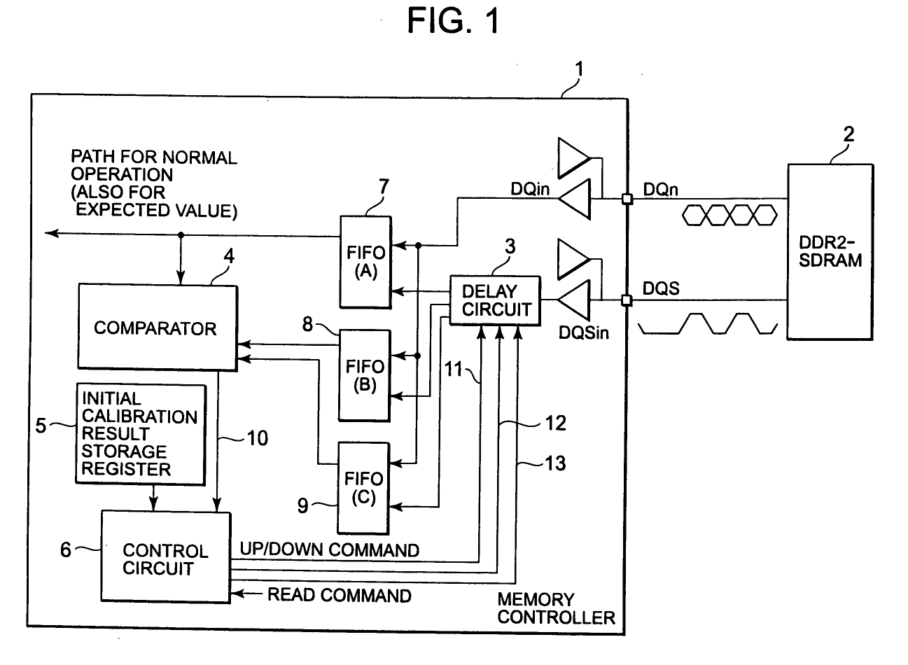

Hereinafter, description is given of an embodiment of the present invention with reference to the accompanying drawings. FIG. 1 is a diagram illustrating a memory controller according to this embodiment. A memory controller 1 according to this embodiment includes a delay circuit 3 for delaying data strobe signals (DQS signals), and at least two FIFO buffer units 7, 8, and 9 for storing data values of data signals (DQ signals) transmitted from a memory 2 based on at least two data strobe signals delayed by the delay circuit 3.

The memory controller 1 further includes a comparator 4 for comparing the data values stored in the at least two FIFO buffer units 7, 8, and 9, and a control circuit 6 for controlling delay time periods for the data strobe signals (DQS signals) by using the delay circuit 3 based on comparison results 10 acquired from the comparator 4.

Hereinafter, detailed description is given of the memory controller according to this embodiment. It should be noted that the memory controller 1 according to this embodiment may be implemented by providing the at least two FIFO buffer units, but the description is given below with regard to a case where three FIFO buffer units are provided.

The delay circuit 3 outputs to the FIFO buffer units 7, 8, and 9 DQS signals obtained by delaying DQS signals by predetermined periods of time, respectively. It should be noted that the delay circuit 3 is a variable delay circuit capable of changing the delay time periods under the control of the control circuit 6, and is constituted by, for example, a delay locked loop (DLL) circuit. Further, one delay circuit 3 is used in FIG. 1, but a plurality of delay circuits may be used.

The delay circuit 3 generates a first DQS signal delayed by a first delay time period (first phase), a second DQS signal delayed by a second delay time period (second phase), and a third DQS signal delayed by a third delay time period (third phase). Then, the delay circuit 3 outputs the generated DQS signals to the first FIFO buffer unit (A) 7, the second FIFO buffer unit (B) 8, and the third FIFO buffer unit (C) 9, respectively.

The FIFO buffer units 7, 8, and 9 are each constituted by a first-in first-out (FIFO) memory for temporarily storing read data. The FIFO buffer units store the data values (expected values) of the data signals (DQ signals) transmitted from the memory 2 based on timings of the delayed DQS signals, respectively.

Specifically, the first FIFO buffer unit (A) 7 stores the data value (expected value) of the data signal (DQ signal) based on the first DQS signal delayed by the first delay time period. The second FIFO buffer unit (B) 8 stores the data value of the data signal (DQ signal) based on the second DQS signal delayed by the second delay time period. The third FIFO buffer unit (C) 9 stores the data value of the data signal (DQ signal) based on the third DQS signal delayed by the third delay time period.

The delay time periods (phases) are set as described below.

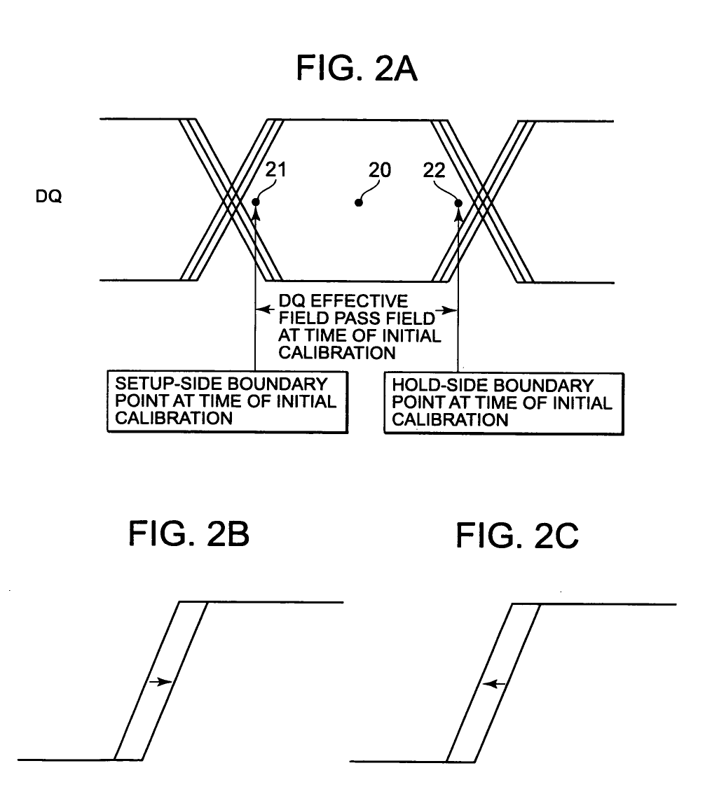

FIG. 2A is an explanatory diagram illustrating a DQ effective field of the memory controller according to this embodiment. The first delay time period (first phase) is set to an optimal phase point 20 corresponding to a center point of the effective field of the DQ signals, which has been determined through the calibration of the memory access timing performed at the time of the initialization.

Further, the second delay time period (second phase) is set to a setup-side boundary point 21 of the effective field of the DQ signals illustrated in FIG. 2A. The setup-side boundary point 21 is a limit point on the setup side, which has been determined through the calibration of the memory access timing performed at the time of the initialization.

Further, the third delay time period (third phase) is set to a hold-side boundary point 22 of the effective field of the DQ signals illustrated in FIG. 2A. The hold-side boundary point 22 is a limit point on the hold side, which has been determined through the calibration of the memory access timing performed at the time of the initialization.

It should be noted that the delay time periods used in the case where two delayed data strobe signals are generated and data values are stored in two FIFO buffer units are set, for example, as described below. The first delay time period (first phase) is set to the optimal phase point 20 corresponding to the center point of the effective field of the DQ signals, which has been determined through the calibration of the memory access timing performed at the time of the initialization. Further, the second delay time period (second phase) is set to the setup-side boundary point 21 or the hold-side boundary point 22 of the effective field of the DQ signals illustrated in FIG. 2A.

The above-mentioned delay time periods are merely examples, and delay time periods may be set as desired within the effective field of the DQ signals.

Further, information pieces on the center point 20, setup-side boundary point 21, and hold-side boundary point 22 of the effective field of the data signals at the time of the initial calibration are stored in an initial calibration result storage register 5. The information pieces stored in the initial calibration result storage register 5 are output to the control circuit 6, and the control circuit 6 controls the respective delay time periods based on those information pieces.

The comparator 4 compares the data values stored in the FIFO buffer units 7, 8, and 9, and outputs comparison results thus obtained to the control circuit 6. Specifically, the comparator 4 compares the data value stored in the first FIFO buffer unit (A) 7 with the data value stored in the second FIFO buffer unit (B) 8. Further, the comparator 4 compares the data value stored in the first FIFO buffer unit (A) 7 with the data value stored in the third FIFO buffer unit (C) 9. Then, the comparator 4 outputs the comparison results 10 thus obtained to the control circuit 6. It should be noted that the comparison results 10 are signals each indicating whether the respective data values “match” or “mismatch” with each other.

It should be noted that the DQ signal output from the first FIFO buffer unit (A) 7 is not only used as collation data for collation with the DQ signals output from the second FIFO buffer unit (B) 8 and the third FIFO buffer unit (C) 9, respectively, but also used for normal operation. In other words, one of the data values stored in the at least two FIFO buffer units is also used for normal operation.

The control circuit 6 changes the delay time periods used by the delay circuit 3 based on the comparison results 10 acquired from the comparator 4. A signal 11 is a signal for controlling the delay time period for the DQS signal output to the first FIFO buffer unit (A) 7. A signal 12 is a signal for controlling the delay time period for the DQS signal output to the second FIFO buffer unit (B) 8. A signal 13 is a signal for controlling the delay time period for the DQS signal output to the third FIFO buffer unit (C) 9.

Specifically, in a case where the data value stored in the first FIFO buffer unit (A) 7 is different from the data value stored in the second FIFO buffer unit (B) 8, the control circuit 6 changes the delay time period (phase) for the second DQS signal. In this case, as illustrated in FIG. 2B, the phase of the second DQS signal is shifted to an inner side (in a direction indicated by an arrow). The control circuit 6 outputs the signal 12 for shifting the phase of the second DQS signal in such a manner as described above to the second FIFO buffer unit (B) 8.

On the other hand, in a case where the data value stored in the first FIFO buffer unit (A) 7 matches with the data value stored in the second FIFO buffer unit (B) 8, it is indicated that there is no change in operational margin on the setup side.

Further, in a case where the data value stored in the first FIFO buffer unit (A) 7 is different from the data value stored in the third FIFO buffer unit (C) 9, the control circuit 6 changes the delay time period for the third DQS signal. In this case, as illustrated in FIG. 2C, the phase of the third DQS signal is shifted to an inner side (in a direction indicated by an arrow). The control circuit 6 outputs the signal 13 for shifting the phase of the third DQS signal in such a manner as described above to the third FIFO buffer unit (C) 9.

On the other hand, in a case where the data value stored in the first FIFO buffer unit (A) 7 matches with the data value stored in the third FIFO buffer unit (C) 9, it is indicated that there is no change in operational margin on the hold side.

Through the operation as described above, the DQ signal effective field during the reading operation may be checked in real time. In other words, with the memory controller according to this embodiment, the DQ effective field may be recognized during the normal memory access, and the optimal phase point may be calculated and updated as appropriate based on the DQ effective field.

Further, the comparison among those data values is performed with respect to read data, and hence is performed within a clock cycle period corresponding to half a burst length with a read command as a trigger after the lapse of a read latency determined on the DRAM. In other periods, there is no read data present, and hence the comparison operation for the expected values is not performed.

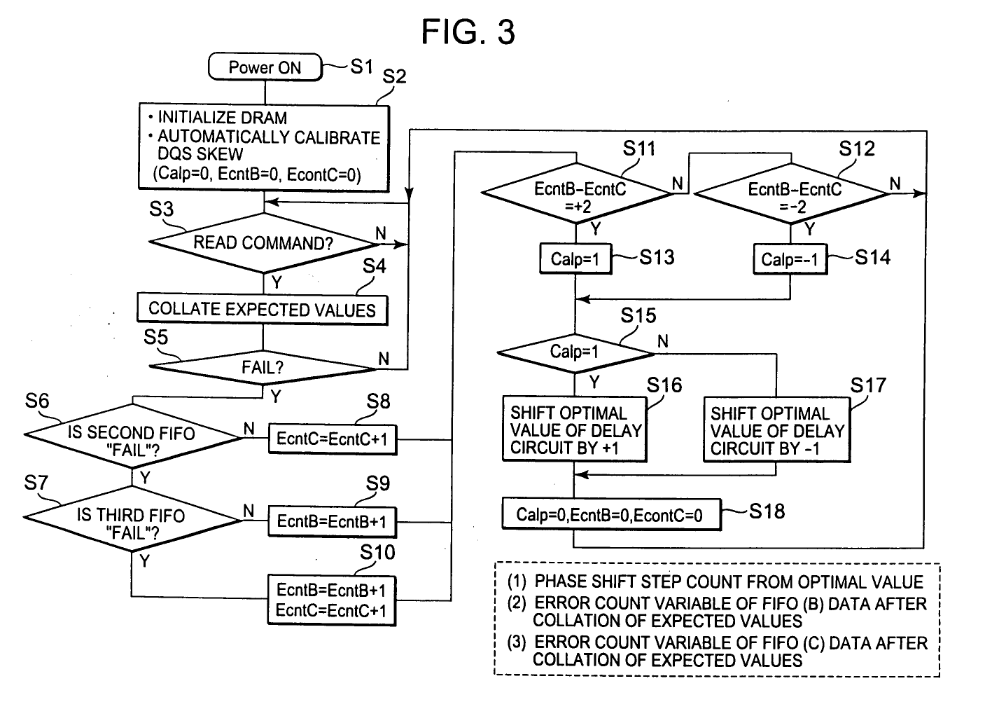

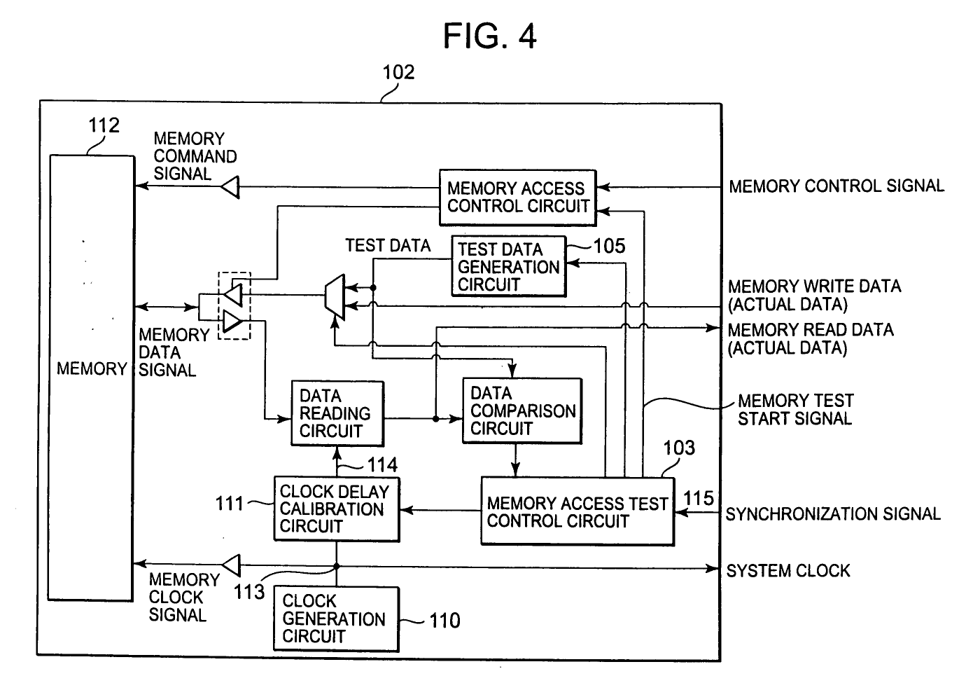

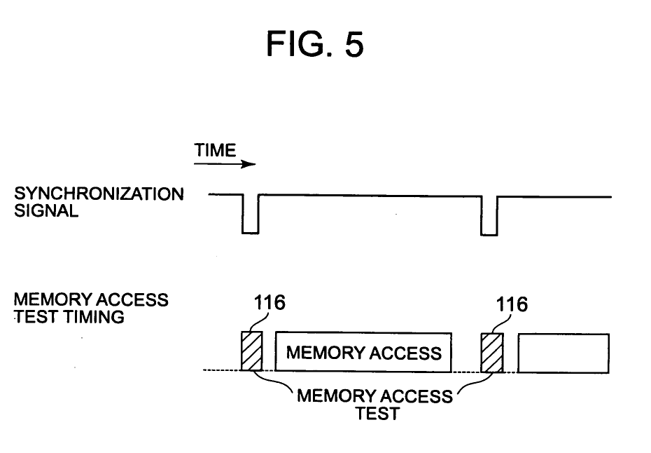

Next, description is given of operation of the memory controller according to this embodiment with reference to FIG. 3.

. First, the memory controller 1 is powered on (S1). When the memory controller 1 is powered on, the DRAM is initialized, and a DQS skew is automatically calibrated (S2). Information pieces on results of the initial calibration at this time are stored in the initial calibration result storage register 5. On this occasion, Calp=0, EcntB=0, and EcntC=0, where Calp represents a phase shift step count from an optimal value, EcntB represents an error count variable of the data value stored in the second FIFO buffer unit (B) 8, and EcntC represents an error count variable of the data value stored in the third FIFO buffer unit (C) 9.

When a read command is output to the control circuit 6 (S3), the comparator 4 compares the data values (expected values) stored in the respective FIFO buffer units 7, 8, and 9 (S4). In a case where the data value stored in the first FIFO buffer unit (A) 7 matches with the data value stored in the second FIFO buffer unit (B) 8, judgment is made as “PASS”. On the other hand, in a case where those data values do not match with each other, judgment is made as “FAIL” (S5). Similarly, in a case where the data value stored in the first FIFO buffer unit (A) 7 matches with the data value stored in the third FIFO buffer unit (C) 9, judgment is made as “PASS”. On the other hand, in a case where those data values do not match with each other, judgment is made as “FAIL” (S5).

In S6 and S7, it is judged which of the following cases applies: (1) the case where judgment is made as “FAIL” for the comparison of the data value stored in the second FIFO buffer unit (B) 8 with the data value stored in the first FIFO buffer unit (A) 7; (2) the case where judgment is made as “FAIL” for the comparison of the data value stored in the third FIFO buffer unit (C) 9 with the data value stored in the first FIFO buffer unit (A) 7; and (3) the case where judgment is made as “FAIL” for both the comparisons of the data values stored in the second FIFO buffer unit (B) 8 and the third FIFO buffer unit (C) 9 with the data value stored in the first FIFO buffer unit (A) 7.

When the case (1) applies, the value of EcntB representing the error count is incremented by 1 (S9). When the case (2) applies, the value of EcntC representing the error count is incremented by 1 (S8). When the case (3) applies, the values of EcntB and EcntC are incremented by 1, respectively (S10).

Subsequently, it is judged whether or not EcntB-EcntC=+2 (S11). In a case where EcntB−EcntC=+2, Calp=1 (S13). In a case where EcntB−EcntC≠+2, it is judged whether or not EcntB−EcntC=−2 (S12). In a case where EcntB−EcntC=−2, Calp=−1 (S14).

On this occasion, adopted for the optimal phase point 20 is the center of the phase position between the setup-side boundary point 21 of the effective field of the DQ signals and the hold-side boundary point 22 of the effective field of the DQ signals, and hence update operation is executed for the first time when the difference between the error counts of the second and third FIFO buffer units becomes 2.

Subsequently, it is judged in S15 whether or not Calp=1.

In a case where Calp=1, the optimal value of the delay circuit is shifted by +1 (S16). On the other hand, in a case where Calp≠1 (in other words, in a case where Calp=−1), the optimal value of the delay circuit is shifted by −1 (S17).

When S16 or S17 is finished, setting is made such that Calp=0, EcntB=0, and EcntC=0 (S18), and the processing returns to S3.

Next, description is given of a memory control method according to this embodiment.

The memory control method according to this embodiment includes: generating at least two delayed data strobe signals; storing data values of data signals transmitted from a memory based on the at least two delayed data strobe signals; comparing the stored data values; and controlling delay time periods for the at least two delayed data strobe signals based on comparison results obtained through the comparing.

The memory control method may be implemented by, for example, the memory controller that has been described in this embodiment.

Further, the memory control method according to this embodiment may further include: generating a first DQS signal delayed by a first delay time period, a second DQS signal delayed by a second delay time period, and a third DQS signal delayed by a third delay time period; storing one of the data values based on the first DQS signal; storing another one of the data values based on the second DQS signal; and storing still another one of the data values based on the third DQS signal.

Further, the memory control method according to this embodiment may further include: setting a phase of the first DQS signal to a center point of an effective field of the data signals; setting a phase of the second DQS signal to a setup-side boundary point of the effective field of the data signals; and setting a phase of the third DQS signal to a hold-side boundary point of the effective field of the data signals.

Further, the memory control method according to this embodiment may further include: changing the delay time period for the second DQS signal in a case where the one of the data values which is stored based on the first DQS signal is different from the another one of the data values which is stored based on the second DQS signal; and changing the delay time period for the third DQS signal in a case where the one of the data values which is stored based on the first DQS signal is different from the still another one of the data values which is stored based on the third DQS signal.

According to the present invention, it is possible to provide the memory controller capable of calibrating the memory access timing even in the case where the application has no blanking interval.

Further, the memory access circuit disclosed in JP 2005-141725 A is implemented by writing and reading a pattern for calibrating the memory access timing directly to and from the memory. Therefore, after the blanking interval is ended, all the data pieces stored in the memory thus far need to be discarded. In contrast, according to the present invention having the above-mentioned configuration, the operation of discarding all the data pieces stored in the memory is unnecessary.

The embodiment of the present invention has been described above, but the present invention is not limited to the configuration described in the above-mentioned embodiment. Needless to say, various modifications, corrections, and combinations may be made thereto, which could be made by a person skilled in the art, and the appended claims cover all such modifications, corrections, and combinations as fall within the true spirit and scope of the present invention.

The present invention is widely applicable to the technical fields such as the field of electronic devices using a memory.

What is claimed is:

1. A memory controller, comprising:
a delay circuit for delaying data strobe signals;
at least two first-in first-out (FIFO) buffer units for storing data values of data signals transmitted from a memory based on at least two of the data strobe signals delayed by the delay circuit, respectively;
a comparator for comparing the data values stored in the at least two FIFO buffer units; and
a control circuit for controlling delay time periods for the at least two of the data strobe signals based on comparison results acquired from the comparator,
wherein one of the data values stored in the at least two FIFO buffer units is used also for normal operation.

2. A memory controller according to claim 1, wherein:
the delayed data strobe signals comprise:
a first data strobe signal delayed by a first delay time period;
a second data strobe signal delayed by a second delay time period; and
a third data strobe signal delayed by a third delay time period; and
the at least two FIFO buffer units comprise:
a first FIFO buffer unit for storing one of the data values based on the first data strobe signal;
a second FIFO buffer unit for storing another one of the data values based on the second data strobe signal; and
a third FIFO buffer unit for storing still another one of the data values based on the third data strobe signal.

3. A memory controller according to claim 2, wherein:
a phase of the first data strobe signal is set to a center point of an effective field of the data signals;
a phase of the second data strobe signal is set to a setup-side boundary point of the effective field of the data signals;
a phase of the third data strobe signal is set to a hold-side boundary point of the effective field of the data signals; and
the one of the data values stored in the first FIFO buffer unit is used also for the normal operation.

4. A memory controller according to claim 3, wherein the control circuit is configured to:
change the second delay time period for the second data strobe signal in a case where the one of the data values stored in the first FIFO buffer unit is different from the another one of the data values stored in the second FIFO buffer unit; and
change the third delay time period for the third data strobe signal in a case where the one of the data values stored in the first FIFO buffer unit is different from the still another one of the data values stored in the third FIFO buffer unit.

5. A memory controller according to claim 3, further comprising an initial calibration result storage register for storing the center point, the setup-side boundary point, and the hold-side boundary point of the effective field of the data signals at a time of initial calibration.

6. A memory controller according to claim 1, wherein the delay circuit comprises a delay locked loop (DLL) circuit.

7. A memory control method, comprising:
generating at least two delayed data strobe signals;
storing data values of data signals transmitted from a memory based on the at least two delayed data strobe signals;
comparing the stored data values;
controlling delay time periods for the at least two delayed data strobe signals based on comparison results obtained through the comparing; and
using one of the data values also for normal operation.

8. A memory control method according to claim 7,
wherein the generating comprises generating a first data strobe signal delayed by a first delay time period, a second data strobe signal delayed by a second delay time period, and a third data strobe signal delayed by a third delay time period, and
wherein the storing comprises:
storing one of the data values based on the first data strobe signal;
storing another one of the data values based on the second data strobe signal; and
storing still another one of the data values based on the third data strobe signal.

9. A memory control method according to claim 8, further comprising:
setting a phase of the first data strobe signal to a center point of an effective field of the data signals;
setting a phase of the second data strobe signal to a setup-side boundary point of the effective field of the data signals; and
setting a phase of the third data strobe signal to a hold-side boundary point of the effective field of the data signals,
wherein the using comprises using the one of the data values stored based on the first data strobe signal also for the normal operation.

10. A memory control method according to claim 9, wherein the controlling comprises:
changing the second delay time period for the second data strobe signal in a case where the one of the data values stored based on the first data strobe signal is different from the another one of the data values stored based on the second data strobe signal; and
changing the third delay time period for the third data strobe signal in a case where the one of the data values stored based on the first data strobe signal is different from the still another one of the data values stored based on the third data strobe signal.
